(19) United States
(12) Patent Application Publication
(10) Pub. No.: US 2003/0177428 A1
(43) Pub. Date: Sep. 18, 2003

(54) Simulation method and apparatus for verifying logic circuit including processor

(75) Inventors: Mitsuo Wakabayashi, Kawasaki (JP); Hidetaka Ebeshu, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 10/334,003

(22) Filed: Dec. 31, 2002

(30) Foreign Application Priority Data
Mar. 18, 2002 (JP) 2002-074395

(51) Int. Cl. G06F 11/00; G01R 31/28

(52) U.S. Cl. 714/741

(57) ABSTRACT

When a model of a logic circuit including a processor is simulated by a simulator for its verification, an error detection process is performed by checking the internal bus of the processor each time the simulator allows the processor to execute one command (S1, S5, S7, S9, S11, S13, S15, and S17). When an error is detected, the error is classified to output its error code and perform a memory dump (S3), and then an abnormal signal is output (S4). In response to this signal, the simulator ends the simulation.

### CROSS-REFERENCE TO RELATED APPLICATIONS

This application is based upon and claims the benefit of priority from the prior Japanese Patent Application No. 2002-074395, filed on Mar. 18, 2002, the entire contents of which are incorporated herein by reference.

### BACKGROUND OF THE INVENTION

1. Field of the Invention

The present invention relates to a simulation method and apparatus for verifying a logic circuit including a processor, and more particularly to a simulation method and apparatus which detect an error and automatically determine the kind of error.

2. Description of the Related Art

FIG. 4 is a schematic block diagram showing the function of a prior art simulation apparatus for verifying a logic circuit.

A logically designed circuit is stored as a model 12 to be verified in a memory 11 of a computer 10. The model includes a processor and is, for example, a one-chip microcomputer. In order to verify the operation of the model 12, it is required to load a test program into a memory included in the model 12. A source code 13 consisting of a test program 131 and expected-value data 132 is converted to a machine code 15 by an assembler 14. The converted test program 151 is loaded into the memory that is a part of the model stored in the memory 11. This model is operated by a simulator 17 to execute the test program 151. During the execution, external signals and external data are provided from the test bench 16 through the simulator 17 to the model, and processing is executed according to the external signals and the external data. The output of the model is provided through the simulator 17 to an output processing section 18, and then compared with the expected-value data 152 included in the machine code 15. The comparison result is output as a log file. In addition, the waveforms of predetermined output signals are output from the output processing section 18. The simulator 17 and the output processing section 18 are programs, together with the assembler 14, and these are stored in a storage device, together with the machine code 15.

When there is a design miss in the model 12 to be verified, the output data of the model is not coincident with the expected-value data.

However, the disparity occurs also when there is a miss in the description of the test program 131 or the test bench 16, and therefore it takes time to find the cause, deteriorating the verification efficiency.

### SUMMARY OF THE INVENTION

Accordingly, it is an object of the present invention to provide a simulation method and apparatus for verifying a logic circuit including a processor, and an error detection program for verifying a logic circuit, which can determine the cause easily and quickly when an error occurs, thereby improving the verification efficiency.

In one aspect of the present invention, there is provided a simulation method for simulating a model of a logic circuit including a processor by a simulator for verification of the model, the simulation method comprising the steps of:

(a) performing an error detection process by checking a bus of the processor each time the simulator causes the processor to execute one command; and

(b) classifying a detected error to output error information including the classified error.

This simulation method allows an operator to easily recognize the kind of error at once by seeing the outputted error information, and to find easily and quickly the detailed cause of error on the basis of the error information. Therefore, it is possible to improve the verification efficiency.

When the step (a) comprises a sub-step of comparing data on a data bus of the bus with a corresponding expected value after other error detection process, the kind of error can be specified even if the data is not coincident with the expected value, provided that said other error is detected before the comparison. This allows finding the cause of error more easily and quickly. In addition, when it is detected that the data is not coincident with the expected value, one can see that said other error does not exist, so that it is possible to find the cause of error more easily and quickly.

Other aspects, objects, and the advantages of the present invention will become apparent from the following detailed description taken in connection with the accompanying drawings.

### BRIEF DESCRIPTION OF THE DRAWINGS

FIG. 1 is a schematic block diagram showing the function of a simulation apparatus for verifying a logic circuit according to one embodiment of the present invention.

FIG. 2 is a block diagram showing an embodiment of the to-be-verified model 20 with error check function, shown in FIG. 1.

FIG. 3 is a schematic flowchart showing a sequence processed by the error detection section 19 of FIG. 2.

FIG. 4 is a schematic block diagram showing the function of a prior art simulation apparatus for verifying a logic circuit.

### DESCRIPTION OF THE PREFERRED EMBODIMENT

Referring now to the drawings, wherein like reference characters designate like or corresponding parts throughout several views, a preferred embodiment of the present invention are described below.

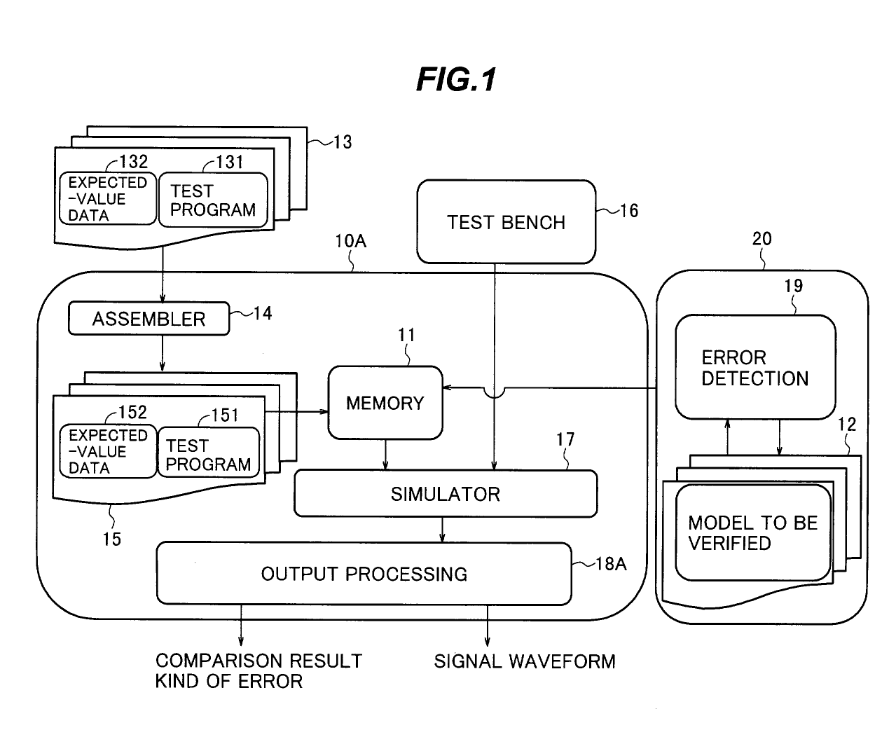

FIG. 1 is a schematic block diagram showing the function of a simulation apparatus for verifying a logic circuit according to one embodiment of the present invention.

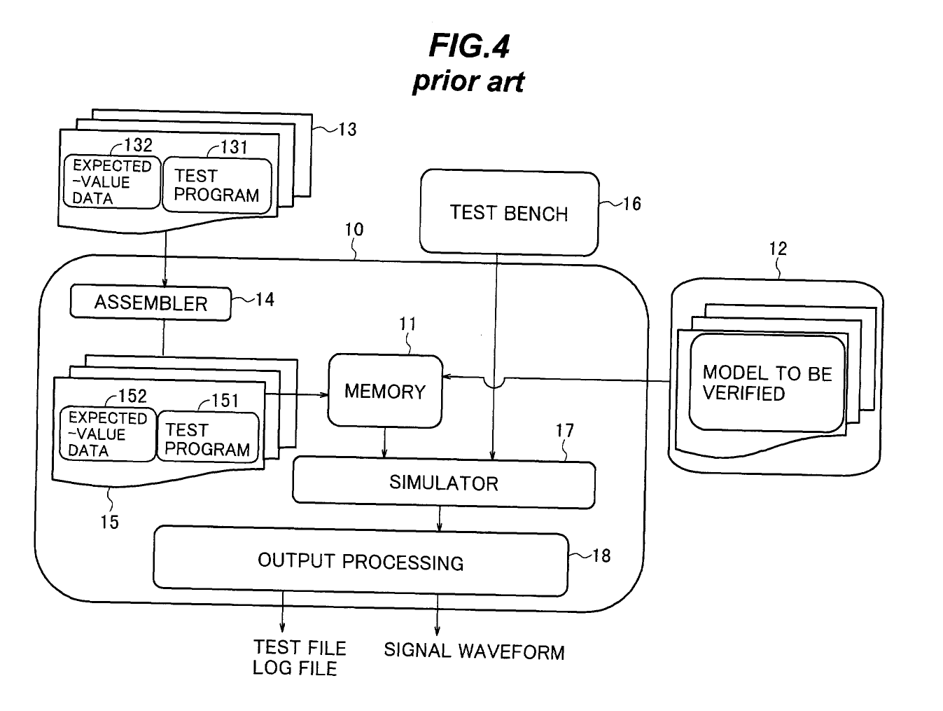

This apparatus differs from the apparatus of FIG. 4 in that a memory 11 has stored therein a to-be-verified model 20 with error check function which includes an error detecting section 19 connected to a model 12 to be verified. Like the model 12 to be verified and the test bench 16, the error detection section 19 has been described in a hardware description language (HDL), for example, Verilog-HDL. Before their executions, the test bench 16 and the to-be-verified model 20 with error check function are converted by a computer 10A to a code easily executable by a computer, and stored in a storage unit in a computer 10A.

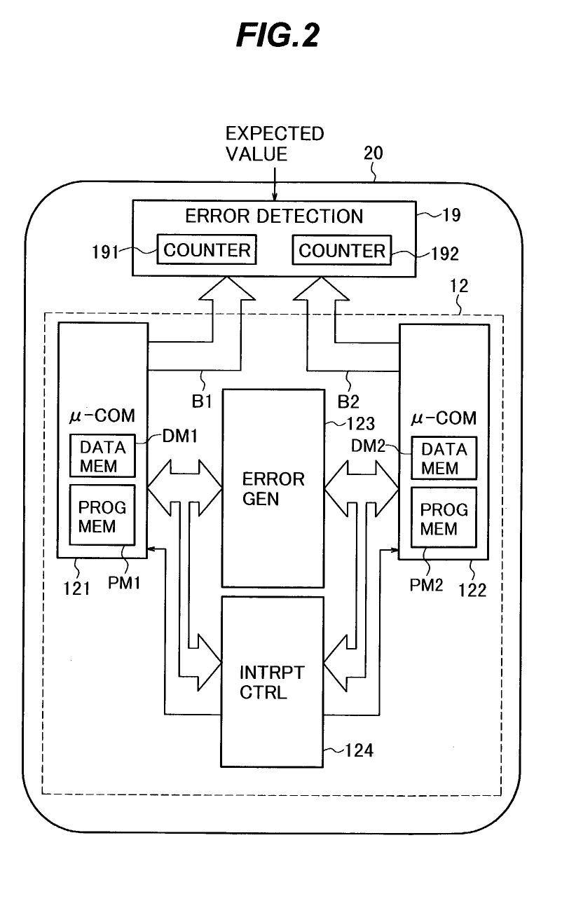

FIG. 2 is a schematic block diagram showing an embodiment of the to-be-verified model 20 with error check function.

The model 12 to be verified includes one-chip microcomputers (μCOMs) 121 and 122 in the same structure. For example, the μCOMs 121 and 122 are ones each incorporated in two separate cellular phones, and reception and transmission of data is made between the μCOMs 121 and 122. The μCOM 121 includes a program memory PM1 and a data memory DM1, and the μCOM 122 includes a program memory PM2 and a data memory DM2. The same test program 151 is loaded into each of the program memories PM1 and PM2.

In order to simulate the operation when an error occurs in transmission or reception of signal, an error generation module 123 to forcibly cause, for example, a bit inversion, is connected between the μCOMs 121 and 122. In addition, an interrupt control module 124 is provided to generate interruptions to the μCOMs 121 and 122 according to reception of signal or key input. The setting of operation of the error generation module 123 and the interrupt control module 124 are made through execution of the test program 151 by the μCOMs 121 or 122.

Internal buses (data bus, address bus, and control bus) of the μCOMs 121 and 122 are connected through buses B1 and B2, respectively, to the error detection section 19. The error detection section 19 checks data on these buses to detect error, and classifies the detected error to output error code. The error detection section 19 includes counters 191 and 192 related to the buses B1 and B2, respectively.

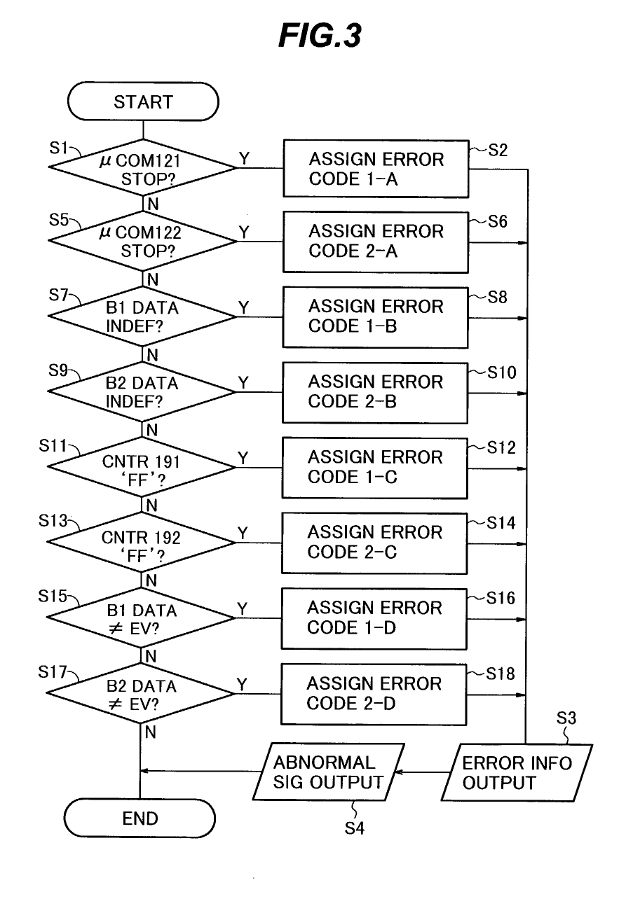

FIG. 3 is a schematic flowchart showing the sequence in the process by the error detection section 19 of FIG. 2. A program corresponding to this flowchart is started up each time the simulator 17 causes the μCOMs 121 and 122 to execute one step of command. The following reference signs in parentheses indicate steps in FIG. 3.

(S1) If the stop of the μCOM 121 is detected, that it, when detected is the stop of system clock included in the control bus of the bus B1, then the process goes to step S2, or else the process goes to step S5.

(S2) Since the error belongs to the μCOM 121, it is classified as error 1, and the stop error of μCOM is classified as error A. Thus, an error code 1_A is assigned to this error. Next, the process goes to step S3.

(S3) The error detection section 19 outputs the classified error identification code, and outputs information that make it easy to find the detailed cause of the error according to contents of the error. For example, the error detection section 19 performs a memory dump. The simulator 17 provides the output of the error detection section 19 to the output processing section 18A. The output detection section 18A provides the error code and the information to an output device not shown.

An operator can easily recognize the kind of error at once by seeing the error code. In addition, it becomes possible to find easily and quickly the detailed cause of error on the basis of the error information. Therefore, the verification efficiency is improved.

(S4) The error detection section 19 outputs an abnormal signal, and in response to this, the simulator 17 terminates the execution of simulation. This allows a quick response to the occurrence of error, and makes it easy to determine the cause of error occurrence.

(S5) If the stop of the μCOM 122 is detected, then the process goes to step S6, or else the process goes to step S7.

(S6) Since the error belongs to the μCOM 122, it is classified as error 2, and the stop error of μCOM is classified as error A. Thus, an error code 2_A is assigned to this error. Next, the process goes to step S3.

(S7) If data on the data bus of the bus B1 is indefinite, then the process goes to step S8, or else the process goes to step S9.

In the simulation, each digit is a ternary of ‘1’, ‘0’, or indefinite, instead of a binary as in actual case. When a miss in the test program 131 causes to read data in the data memory DM1 without initializing it in advance, or read non-initialized data because of a mistaken address, the indefinite data is appeared on the data bus. In addition, the data becomes indefinite when there is a collision in data on the bus, which case corresponds to a miss in logic design of the model 12.

(S8) Since the error belongs to the μCOM 121, it is classified as error 1, and the indefinite data is classified as error B. Thus, an error code 1_B is assigned to this error. Next, the process goes to step S3. In step S3, a memory dump is performed for the vicinity of the address of this indefinite data as mentioned above.

(S9) If the data on the data bus of the bus B2 is indefinite, then the process goes to step S10, or else the process goes to S11.

(S10) Since the error belongs to the μCOM 122, it is classified as error 2, and the indefinite data is classified as error B. Thus, an error code 2_B is assigned to this error. Next, the process goes to step S3.

(S11) In normal operation, if an unlikely data sequence occurs, for example, when data with all bits ‘1’ is appeared 255 times sequentially on the data bus of the bus B1, it is determined as an error. Thus, if the bits on the data bus of the bus B1 are all ‘1’, then the error detection section 19 increments the counter 191, or else it resets the counter 191. If the count of the counter 191 are ‘FF’ in hexadecimal, then the process goes to step S12, or else the process goes to step S13.

(S12) Since the error belongs to the μCOM 121, it is classified as error 1, and the unlikely data sequence is classified as error C. Thus, an error code 1_C is assigned to this error. Next, the process goes to step S3. In step S3, a memory dump is performed for the vicinity of the addresses of this unlikely data sequence.

(S13) If the bits on the data bus of the bus B2 are all ‘1’, then the error detection section 19 increments the counter 192, or else it resets the counter 192. If the count of the counter 192 are ‘FF’ in hexadecimal, the process goes to step S14, or else the process goes to step S15.

(S14) Since the error belongs to the μCOM 122, it is classified as error 2, and the unlikely data sequence is classified as error C. Thus, an error code 2_C is assigned to this error. Next, the process goes to step S3. In step S3, a memory dump is performed for the vicinity of the addresses of this unlikely data sequence.

(S15) If the address value on the address bus of the bus B1 is within the address range of the data memory DM1, and a read operation is going, a comparison is made between data on the data bus of the bus B1 and the corresponding one in the expected-value data 152. If the comparison result shows there is a disparity therebetween, then the process goes to step S16, or else the process goes to step S17.

Since the error determination of step S15 is made after other error determinations, even if the data is not coincident with the expected value, the kind of error is specified when it is determined there is an error before step S15. This makes it possible to find the cause of error more easily and quickly. In addition, when it is determined there is an error in step S15, one can see there is no other error, so that it is possible to find the cause of error more easily and quickly.

(S16) Since the error belongs to the μCOM 121, it is classified as error 1, and the disparity with the expected value is classified as error D. Thus, an error code 1_D is assigned to this error. Next, the process goes to step S3. In step S3, a memory dump is performed for the vicinity of the address of this data.

(S17) If the address value on the address bus of the bus B2 is within the address range of the data memory DM2, and a read operation is going, a comparison is made between data on the data bus of the bus B2 and the corresponding one in the expected-value data 152. If the comparison result shows there is a disparity therebetween, then the process goes to step S18, or else the process terminates the error detection for one step of command execution of the simulation.

(S18) Since the error belongs to the μCOM 122, it is classified as error 2, and the disparity with the expected value is classified as error D. Thus, an error code 2_D is assigned to this error. Next, the process goes to step S3. In step S3, a memory dump is performed for the vicinity of the address of this data.

The error detection section 19 performing the above-mentioned process can be applied to various types of processor models. In addition, further improvement in efficiency of failure detection can be made by modifying the program so as to detect an error that is actually generated but could not be detected in the process of FIG. 3. It is relatively simple to realize the improvement.

The following TABLE I shows a program list described in Verilog-HDL as a detailed example of the process in step S7, and step S3 in the case where an affirmative determination is made in step S7.

```
TABLE I
      ¦
      ¦
      ¦
reg [7:0]error_count1. error_count2;
initial
  begin
  error_count1=8′h0;
  error_count2=8′h0;
  end
always @(negedge kab1)
  if((rb1==16′hffff)&^{˜}ale1&^{˜}RST1&RSTX&(error _count1!=8′h20))
    begin
    error_count1=error_count1+1;
    end
  else if((error_count1==8′h20)&(rb1==16′hffff)&^{˜}ale1&^{˜}RST1&RSTX)
    begin
    $display(“***** Error1!! Please check a program1 or logic. *****”);
    if(memory_dump)
      begin
      file_name1=$fopen(“message_dump1”);
      file_name2=$fopen(“message_dump2”);
      file_name3=$fopen(“mem_dump1”);
      file_name4=$fopen(“mem_dump2”);
      for(loop1=0;loop1<word_mem;loop1=loop1+1)
      ¦
      ¦
      ¦
```

The following TABLE II shows a program list described in Verilog-HDL as a detailed example of the process in step S11, and step S3 in the case where an affirmative determination is made in step S11.

```
TABLE II
    ¦
    ¦
    ¦
    ¦
    ¦
    ¦
else if(^{˜}RST1&RSTX&rbwr1&ale1&((rb1[15]===1′bx)|(rb1[14]===1′bx)|(rb1[13]===1′bx)|
        (rb1[12]===1′bx)|(rb1[11]===1′bx)|(rb1[10]===1′bx)|(rb1[9]===1′bx)|
        (rb1[8]===1′bx)|(rb1[7]===1′bx)|(rb1[6]===1′bx)|(rb1[5]===1′bx)|
        (rb1[4]===1′bx)|(rb1[3]===1′bx)|(rb1[2]===1′bx)|(rb1[1]===1′bx)|(rb1[0]===1′bx)))
  begin
  @(posedge kab1)
  $display(“***** CPU Store Error1(output=X)!! Please check. *****”);
  $finish;
  end
else if(^{˜}RST1&RSTX&¹⁸ rbwr1&ale1&(pc1[23:16]==8′h00)&(
        (rb1[7]===1′bx)|(rb1[6]===1′bx)|(rb1[5]===1′bx)|(rb1[4]===1′bx)|(rb1[3]===1′bx)|
        (rb1[2]===1′bx)|(rb1[1]===1′bx)|(rb1[0]===1′bx)))
  begin
  @(posedge kab1) /* A case where read data is indefinite “X” */
  $display(“***** Error1!! I/0 data or Internal RAM data read X *****”);
  $finish;
  end
else if(p011===1′b0)
  begin
  @(posedge kab1)
  $display(“***** Error1!! Data Compare error *****”);
  if(memory_dump)
    begin
    file_name1=$fopen(“message_dump1”);
    file_name2=$fopen(“message_dump2”);
    file_name3=$fopen(“mem_dump1”);
    file_name4=$fopen(“mem_dump2”);
    for(loop1=0;loop1<word_mem;loop1=loop1+1)
    ¦
    ¦
    ¦
    ¦
    ¦
```

Although a preferred embodiment of the present invention have been described, it is to be understood that the invention is not limited thereto and that various changes and modifications may be made without departing from the spirit and scope of the invention.

For example, together with the memory dump, it is also possible to perform a register dump in a range from the present time back to a predetermined time ago. Further, the present invention may be constituted so as to detect any kind of errors other than the above-mentioned ones.

What is claimed is:

1. A simulation method for simulating a model of a logic circuit including a processor by a simulator for verification of the model, the simulation method comprising the steps of:
(a) performing an error detection process by checking a bus of the processor each time the simulator causes the processor to execute one command; and
(b) classifying a detected error to output error information including the classified error.

2. The simulation method according to claim 1, wherein the step (a) comprises a sub-step of comparing data on a data bus of the bus with a corresponding expected value after other error detection process.

3. The simulation method according to claim 2, wherein the model includes a memory coupled to the processor; each digit of data on the data bus is ‘1’, ‘0’ or an indefinite state; and each digit of data in the memory has the indefinite state before initializing the data with a binary code; and
said other error detection process in the step (a) includes a sub-step of detecting whether data on the data bus is in the indefinite state.

4. The simulation method according to claim 2, wherein said other error detection process in the step (a) includes a sub-step of detecting whether data on the data bus continuously maintains a predetermined value more than a predetermined number of times to determine as a error.

5. The simulation method according to claim 2, wherein the error information in the step (b) includes an error code indicating a kind of error.

6. The simulation method according to claim 3, wherein the error information in the step (b) includes a memory dump of a predetermined range including an address at which an error has occurred.

7. The simulation method according to claim 4, wherein the error information in the step (b) includes a memory dump of a predetermined range including an address at which an error has occurred.

8. The simulation method according to claim 1, further comprising the step of:
(c) stopping operation of the simulator when an error has been detected.

9. A computer program product, comprising: a computer readable storage medium having a computer program stored thereon, the computer program being an error detection program for verifying a model of a logic circuit including a processor, the computer program being used while the logic circuit is simulated by a simulator for verification the model, the computer program causing a computer to execute the steps of:
(a) performing an error detection process by checking a bus of the processor each time the simulator causes the processor to execute one command; and
(b) classifying a detected error to output error information including the classified error.

10. The computer program product according to claim 9, wherein the step (a) comprises a sub-step of comparing data on a data bus of the bus with a corresponding expected value after other error detection process.

11. The computer program product according to claim 10, wherein the model includes a memory coupled to the processor; each digit of data on the data bus is ‘1’, ‘0’ or an indefinite state; and each digit of data in the memory has the indefinite state before initializing the data with a binary code; and
said other error detection process in the step (a) includes a sub-step of detecting whether data on the data bus is in the indefinite state.

12. The computer program product according to claim 10, wherein said other error detection process in the step (a) includes a sub-step of detecting whether data on the data bus continuously maintains a predetermined value more than a predetermined number of times to determine as a error.

13. The computer program product according to claim 10, wherein the error information in the step (b) includes an error code indicating a kind of error.

14. A simulation apparatus for verifying a logic circuit, comprising:
a processor; and
a storage device coupled to the processor,
wherein the storage device stores:
a simulation program causing the processor to simulate a model of a logic circuit including a processor; and
an error detection program, for verifying the logic circuit, causing the processor to execute the steps of:
(a) performing an error detection process by checking a bus of the processor each time the simulator causes the processor to execute one command; and
(b) classifying a detected error to output error information including the classified error.
